(19) United States
(12) Patent Application Publication
(10) Pub. No.: US 2026/0314426 A1
(43) Pub. Date: Oct. 8, 2026

(54) SEMICONDUCTOR DEVICE INCLUDING CHARGE SHIELDING LAYER

(71) Applicant: Samsung Electronics Co., Ltd., Suwon-si (KR)

(72) Inventors: Guifu Yang, Suwon-si (KR); Bitna Kim, Suwon-si (KR); Sung-Hwan Jang, Suwon-si (KR)

(73) Assignee: Samsung Electronics Co., Ltd., Suwon-si (KR)

(21) Appl. No.: 19/571,674

(22) Filed: Mar. 19, 2026

(30) Foreign Application Priority Data
Apr. 7, 2025 (KR) 10-2025-0044978

(51) Int. Cl. H10W 42/20; H10B 12/00; H10B 80/00; H10D 80/30; H10W 90/00; H10W 90/26

(52) U.S. Cl. CPC H10W 42/281; H10B 12/50; H10W 90/26; H10B 80/00; H10D 80/30; H10W 90/792

(57) ABSTRACT

The present disclosure relates to a semiconductor device, and the semiconductor device comprises a peripheral circuit structure comprising a substrate having a first surface and a second surface facing one another, the substrate comprising first impurity regions and a second impurity region positioned between the first impurity regions, a peripheral circuit positioned on the first surface of the substrate, and a first peripheral buffer layer positioned on the second surface of the substrate, a cell structure overlapping with the peripheral circuit structure, and a charge shielding layer positioned between the substrate and the first peripheral buffer layer, wherein the cell structure comprises a plurality of memory cells comprising memory transistors and capacitors, and word lines and bit lines connected to the memory transistors.

### CROSS-REFERENCE TO RELATED APPLICATIONS

This present application claims priority to and the benefit under 35 U.S.C. § 119(a)-(d) of Korean Patent Application No. 10-2025-0044978 filed on Apr. 7, 2025, in the Korean Patent Office, the entire disclosure of which is incorporated herein by reference.

### FIELD

The present disclosure relates to a semiconductor device and more particularly to a semiconductor device including a charge shielding layer.

### BACKGROUND

Technologies are required to increase the integration density of semiconductor devices. For two-dimensional semiconductor devices, the integration density is mainly determined by the area occupied by the unit memory cell, and this aspect of integration density may be affected by the level of fine pattern formation technology.

However, since the fine pattern formation technology requires expensive equipment, the integration of two-dimensional semiconductor devices is increasing, but is still limited. Accordingly, three-dimensional semiconductor memory devices having three-dimensionally arranged memory cells are being proposed.

### SUMMARY

The embodiments are intended to provide a semiconductor device with improved electrical characteristics.

According to embodiments, a semiconductor device comprises a peripheral circuit structure comprising a substrate having a first surface and a second surface facing one another, the substrate comprising first impurity regions and a second impurity region positioned between the first impurity regions, a peripheral circuit positioned on the first surface of the substrate, and a first peripheral buffer layer positioned on the second surface of the substrate, a cell structure overlapping with the peripheral circuit structure, and a charge shielding layer positioned between the substrate and the first peripheral buffer layer, wherein the cell structure comprises a plurality of memory cells comprising memory transistors and capacitors, and word lines and bit lines connected to the memory transistors.

According to embodiments, a semiconductor device comprises a first substrate and a cell structure positioned on the first substrate, the cell structure comprising a plurality of memory cells, a peripheral circuit structure comprising a second substrate having a first impurity regions and a second impurity region positioned between the first impurity regions, a peripheral circuit positioned on the second substrate, and a first peripheral buffer layer positioned beneath the second substrate, the peripheral circuit structure being overlapping with the cell structure, and a charge shielding layer positioned between the first and second substrates, wherein the cell structure comprises a gate stack structure in which a plurality of word lines and a plurality of interlayer insulating layers are alternately stacked, a plurality of channel patterns arranged at intervals along a direction perpendicular to the first substrate, bit lines extending in the direction perpendicular to the first substrate and connected to one end of each of the channel patterns, and capacitors connected to the other ends of the respective channel patterns.

According to embodiments, a semiconductor device comprises a first substrate and a cell structure comprising a plurality of memory cells positioned on the first substrate, a peripheral circuit structure positioned on the cell structure, the peripheral circuit structure comprising a second substrate comprising first impurity regions and a second impurity region positioned between the first impurity regions, a peripheral circuit positioned on the second substrate and a peripheral buffer layer positioned beneath the second substrate, and a charge shielding layer covering a bottom surface of the second impurity region in the second substrate.

According to embodiments, a method of manufacturing a semiconductor device comprises forming a cell structure including a first substrate and a plurality of memory cells disposed on a front surface of the first substrate, forming a peripheral circuit on a front surface of a second substrate, performing a wafer thinning process on a rear surface of the second substrate until an insulating pattern located inside the second substrate is exposed, forming a charge shielding layer on the rear surface of the second substrate, forming a first peripheral buffer layer covering the charge shielding layer, bonding the first peripheral buffer layer to the cell structure, and forming a peripheral wiring structure that covers the second substrate, the insulating pattern, and the peripheral circuit.

In the method of manufacturing a semiconductor device according to embodiments, the first peripheral buffer layer may have a positive charge.

In the method of manufacturing a semiconductor device according to embodiments, the step of forming the charge shielding layer may include forming the charge shielding layer using a low-pressure chemical vapor deposition (LPCVD) process, a chemical vapor deposition (CVD) process, or a selective epitaxial growth (SEG) process.

In the method of manufacturing a semiconductor device according to embodiments, the step of forming the charge shielding layer may include forming the charge shielding layer to cover a portion of the rear surface of the second substrate.

In the method of manufacturing a semiconductor device according to embodiments, the step of forming the charge shielding layer may include forming the charge shielding layer to cover the entire rear surface of the second substrate.

In the method of manufacturing a semiconductor device according to embodiments, the step of forming the charge shielding layer may include performing a dopant activation process on the charge shielding layer.

In the method of manufacturing a semiconductor device according to embodiments, the dopant activation process may include a laser annealing process.

In the method of manufacturing a semiconductor device according to embodiments, the charge shielding layer may comprise single crystalline silicon, polycrystalline silicon, or amorphous silicon.

In the method of manufacturing a semiconductor device according to embodiments, the charge shielding layer may comprise B-doped Si or B-doped SiGe.

In the method of manufacturing a semiconductor device according to embodiments, the method may further include forming a second peripheral buffer layer having a negative charge between the second substrate and the first peripheral buffer layer, and the charge shielding layer may comprise P-doped Si, P-doped SiGe, As-doped Si, or As-doped SiGe.

### BRIEF DESCRIPTION OF THE DRAWINGS

FIG. 1 is a plan view schematically illustrating a portion of a semiconductor device according to embodiments.

FIG. 2 is a circuit diagram of a memory cell array of a semiconductor device according to embodiments.

FIG. 3 is a perspective view of a memory cell layer of a semiconductor device according to embodiments.

FIG. 4 is a cross-sectional view of a semiconductor device according to embodiments.

FIGS. 5 and 6 are enlarged views of region M of FIG. 4 according to some embodiments.

FIG. 7 is a cross-sectional view of a semiconductor device according to embodiments.

FIG. 8 is a cross-sectional view of a semiconductor device according to embodiments.

FIGS. 9 and 10 are enlarged views of region N of FIG. 8 according to some embodiments.

FIG. 11 is a cross-sectional view of a semiconductor device according to embodiments.

FIGS. 12 to 18 are intermediate step drawings for explaining a method of manufacturing a semiconductor device according to embodiments.

### DETAILED DESCRIPTION

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and thickness of each component shown in the drawing are arbitrarily shown for convenience of explanation, so the present disclosure is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is “over” or “on” another part, this comprises not only cases where it is “directly over” the other part, but also cases where there are other parts in between. Conversely, when we say that a part is “directly above” another part, we mean that there is no other part in between. Also, being “above” or “on” a reference part means being positioned above or below the reference part, and does not necessarily mean being positioned “above” or “on” the opposite direction of gravity.

Additionally, throughout the specification, whenever a part is said to “include” a component, this does not mean that it excludes other components, but rather that it may include other components, unless otherwise specifically stated.

Additionally, throughout the specification, when we say “in plan”, we mean when the target portion is viewed from above, and when we say “in cross section”, we mean when the target portion is viewed from the side in a cross-section cut vertically.

Additionally, throughout the specification, two directions parallel to and intersecting the upper surfaces of the first substrate and the second substrate are defined as the first direction X and the second direction Y, respectively, and the direction perpendicular to the upper surfaces of the first substrate and the second substrate is described as the third direction Z. For example, the first direction X and the second direction Y may be orthogonal to one another.

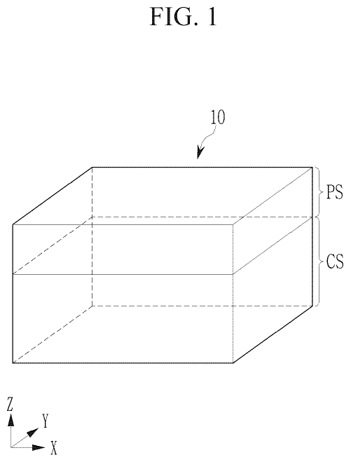

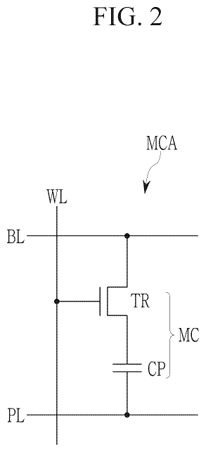

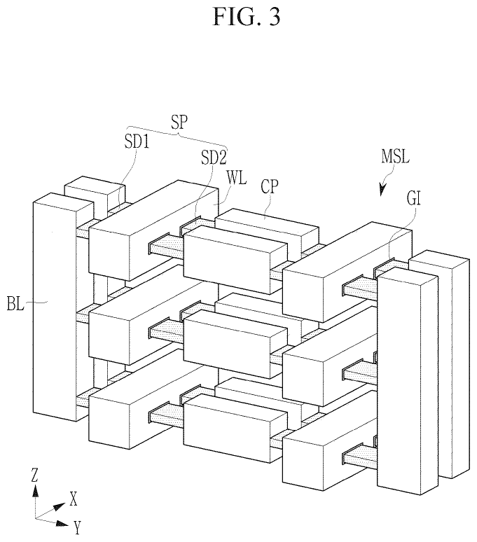

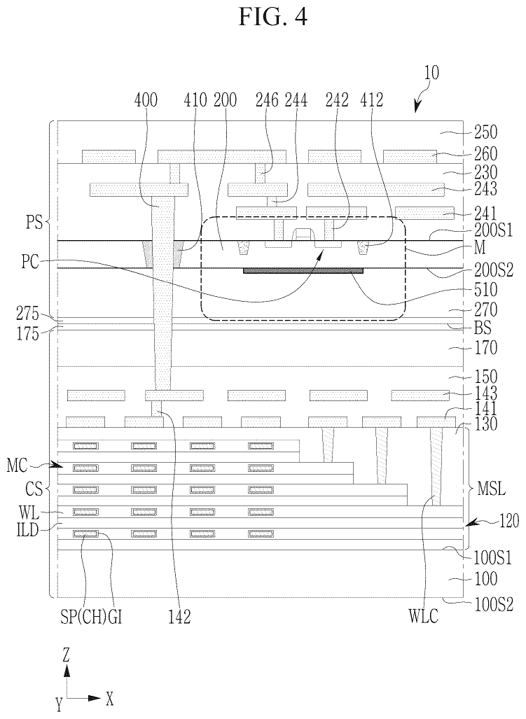

FIG. 1 is a plan view schematically illustrating a portion of a semiconductor device according to embodiments. FIG. 2 is a circuit diagram of a memory cell array of a semiconductor device according to embodiments. FIG. 3 is a perspective view of a memory cell layer of a semiconductor device according to embodiments. FIG. 4 is a cross-sectional view of a semiconductor device according to embodiments.

Referring to FIGS. 1 to 4, a semiconductor device 10 according to embodiments may include a cell structure CS and a peripheral circuit structure PS that overlap one another in a vertical direction.

According to embodiments, the cell structure CS and the peripheral circuit structure PS may be sequentially stacked. In other words, the peripheral circuit structure PS may be positioned on top of the cell structure CS. However, it is not limited to this, and the stacking relationship between the cell structure CS and the peripheral circuit structure PS may be changed in various ways. For example, unlike what is shown, the cell structure CS may be positioned on top of the peripheral circuit structure PS.

According to embodiments, a cell structure CS may include a plurality of memory cells MC and a memory cell array MCA comprising the memory cells. A plurality of memory cells MC and a memory cell array MCA comprising the memory cells may be positioned in a memory cell layer MSL of a cell structure CS described below.

According to embodiments, a memory cell array MCA may have a plurality of memory cells MC arranged in a row direction and a column direction for storing data. A memory cell array MCA may output data from, or write data into, a memory cell MC specified by a row and column address.

Specifically, as illustrated in FIG. 2, one memory cell array MCA may include a bit line BL, a word line WL, and a memory cell MC connected to them.

According to embodiments, a memory cell MC may include one memory transistor TR and one capacitor CP. A capacitor CP may function as a memory element by forming two distinguishable logic states depending on whether charge is stored or not.

According to embodiments, a gate electrode of a memory transistor TR may be connected to a word line WL. A first source/drain electrode of the memory transistor TR may be connected to one terminal of a capacitor CP, and a second source/drain electrode of the memory transistor TR may be connected to a bit line BL. The other terminal of the capacitor CP may be connected to the plate line PL. For example, a plate line PL may be a wiring that applies a bias voltage to a capacitor CP when a memory cell MC operates.

Although not illustrated, the peripheral circuit structure PS may include a core region and a peri region. The core region and peripheral region may be collectively referred to as the logic region or the peripheral circuit region.

According to embodiments, the core region may include a core bank, and the core bank may include core circuits such as a word line driver, a sense amplifier, a row decoder, a column decoder, and a read/write circuit.

According to embodiments, the peripheral region may include peripheral circuits such as a timing register, an address register, a data input register, a data output register, and a data input/output terminal.

According to embodiments, the peripheral circuit structure PS may include peripheral circuitry PC for driving components positioned in the cell structure CS. For example, the peripheral circuit PC may include the core circuit and/or the peripheral circuit described above.

According to embodiments, the cell structure CS may include a first substrate 100 and a plurality of memory cells MC positioned on the first substrate 100.

According to embodiments, the first substrate 100 may have a first surface 100S1 and a second surface 100S2. For example, the first surface 100S1 of the first substrate 100 may correspond to the upper surface, and the second surface 100S2 may correspond to the lower surface. In the present disclosure, two directions parallel to and intersecting with the first surface 100S1 of the first substrate 100 are defined as the first direction X and the second direction Y, respectively, and the direction perpendicular to the first surface 100S1 of the first substrate 100 is defined as the third direction Z. The first direction X and the second direction Y may be orthogonal to one another.

According to embodiments, the first substrate 100 may include a semiconductor material. For example, the first substrate 100 may be a semiconductor substrate comprising a semiconductor material, such as a single crystal Si substrate, a silicon-germanium (Si—Ge) substrate, or an SOI (Si-On-Insulator) substrate. As another example, the first substrate 100 may be a semiconductor epitaxial layer comprising a semiconductor material. However, the type of the first substrate 100 is not limited to this and may be changed in various ways.

According to embodiments, a plurality of memory cells MC may be arranged in a first direction X and a second direction Y. A plurality of memory cells MC may be stacked in a third direction Z perpendicular to the first surface 100S1 of the first substrate 100. A plurality of memory cells MC may have a three-dimensional array structure. A plurality of memory cells MC may be referred to as a memory cell array MCA.

According to embodiments, the cell structure CS may include a gate stack structure 120 in which word lines WL and interlayer dielectric layerss ILD are alternately stacked in a third direction Z perpendicular to a first surface 100S1 of a first substrate 100. The word line WL and the interlayer dielectric layers ILD may extend in a direction parallel to the first surface 100S1 of the first substrate 100 (e.g., in the first direction (X)). The word line WL and the interlayer dielectric layers ILD may have a longer length extending in the first direction X as they are closer to the first substrate 100. Accordingly, the gate stack structure 120 may have a step-like structure in cross section. In other words, the ends of the plurality of word lines WL and the plurality of interlayer dielectric layers ILD may have steps.

According to embodiments, a memory cell layer MSL of a cell structure CS may include a plurality of bit lines BL spaced in a direction parallel to a first surface 100S1 of a first substrate 100 (e.g., a first direction (X)) on the outside of a gate stack structure 120. Each of the plurality of bit lines BL may extend in a third direction Z perpendicular to the first surface 100S1 of the first substrate 100.

According to embodiments, each of the plurality of memory cells MC may be connected to a bit line BL and a word line WL. When voltage is applied to the word line WL and bit line BL, a read or write operation of data may be performed on the memory cell MC. The word line WL may be referred to as the gate electrode.

According to embodiments, each of the plurality of memory cells MC may include a semiconductor pattern SP. The semiconductor patterns SP may be spaced along the third direction Z and extend in the second direction Y.

According to embodiments, each of the plurality of semiconductor patterns SP may include a first impurity pattern SD1 positioned on one side of a word line WL, a second impurity pattern SD2 positioned on the other side of the word line WL, and a channel pattern CH positioned between the first impurity pattern SD1 and the second impurity pattern SD2.

According to embodiments, the first impurity pattern SD1 and the second impurity pattern SD2 may each be a region doped with an impurity (e.g., an n-type or p-type impurity). The first impurity pattern SD1 and the second impurity pattern SD2 of the semiconductor pattern SP may form a source/drain region of a memory transistor (e.g., a memory transistor (TR) of FIG. 2) of the memory cell MC. A channel pattern CH of a semiconductor pattern SP may be surrounded by a word line WL.

According to embodiments, the semiconductor pattern SP may penetrate the word line WL in the second direction Y. One end of the semiconductor pattern SP along the second direction Y may be connected to a bit line BL, and the other end along the second direction Y may be connected to a capacitor CP. One end along the second direction Y of the channel pattern CH may be in contact with the bit line BL, and the other end along the second direction Y may be in contact with the capacitor. A first impurity pattern SD1 of a semiconductor pattern SP may be connected to a bit line BL, and a second impurity pattern SD2 may be connected to a capacitor CP.

According to embodiments, the channel pattern CH may penetrate the word line WL in the second direction Y, and the word line WL may have a structure (in other words, a Gate All Around (GAA) structure) that entirely surrounds the side surfaces of the channel pattern CH of the semiconductor pattern SP.

According to embodiments, a first impurity pattern SD1 of a semiconductor pattern SP may be connected to a bit line BL and function as a first source/drain region, and a second impurity pattern SD2 may be connected to a capacitor CP and function as a second source/drain region. The channel pattern CH between the first impurity pattern SD1 and the second impurity pattern SD2 may function as a channel region of a memory transistor TR.

A semiconductor device 10 according to embodiments may further include a gate insulating film GI positioned between a channel pattern CH and a word line WL.

In embodiments, a gate insulating film GI may surround a channel pattern CH. The channel pattern CH may be separated from the word line WL by a gate insulating film GI. The gate insulating film GI may not be in contact with the first impurity pattern SD1 and the second impurity pattern SD2 of the semiconductor pattern SP. However, it is not limited thereto, and the channel pattern CH may extend in the second direction Y on one side of the word line WL, and a gate insulating film GI may be positioned between the one side of the word line WL and the channel pattern CH.

In the above-described embodiment, the semiconductor device is described as a vertically stacked dynamic random access memory VSDRAM in which a plurality of memory cells MC are vertically stacked, but is not necessarily limited thereto. For example, the semiconductor device may be changed into various memory devices such as DRAM comprising vertical channel transistor (VCT) or buried channel array transistor (BCAT), vertical NAND flash memory, 3D FeFET (Ferroelectric FET), 3D monolithic, etc.

A semiconductor device 10 according to embodiments comprises a memory cell layer MSL and may further include a first cell insulating layer 130 covering a gate stack structure 120.

According to embodiments, the first cell insulation layer 130 may cover the upper surface and side surfaces of the gate stack structure 120. In other words, the first cell insulation layer 130 may cover the upper surface of the word line WL positioned at the top of the gate stack structure 120 and the side surface of the word line WL and the interlayer insulation layer ILD constituting the side surface of the gate stack structure 120.

According to embodiments, the cell structure CS may further include a second cell insulation layer 150 positioned over a memory cell layer MSL, a first cell wiring layer 141, a second cell wiring layer 143, and a first cell via 142 positioned within the second cell insulation layer 150.

According to embodiments, the first cell wiring layer 141 and the second cell wiring layer 143 may be positioned at different levels within the second cell insulation layer 150. The first cell wiring layer 141 and the second cell wiring layer 143 may be connected to one another by the first cell via 142.

In FIG. 4, the cell structure CS is illustrated as comprising a first cell wiring layer 141, a second cell wiring layer 143, and one first cell via 142 connecting them, but the number of cell wiring layers and cell vias included in the cell structure CS and/or their connection relationship may be variously changed.

According to embodiments, the cell structure CS may include a word line contact WLC connecting a word line WL and a first cell wiring layer 141. A word line contact WLC may be connected to a word line WL by penetrating the first cell insulating layer 130. The word line contact WLC may be surrounded by a first cell insulating layer 130.

In embodiments, the word line contact WLC may extend in a third direction Z. A word line contact WLC may have a pillar shape in cross-section. For example, a word line contact WLC may have a sloped side surface so that the width becomes narrower as it approaches the first substrate 100 according to the aspect ratio in cross-section. However, the cross-sectional shape of the word line contact WLC is not limited to this and may be changed in various ways.

Although not shown, the cell structure CS may further include bit line contacts (not shown) that penetrate the first cell insulating layer 130 and connect a plurality of bit lines BL positioned on the outside of the gate stack structure 120 to the first cell wiring layer 141.

According to embodiments, one end of the word line contact WLC along the third direction Z may be connected to the word line WL, and the other end along the third direction Z may be connected to the first cell wiring layer 141.

According to embodiments, each of the bit line BL, the word line WL, the word line contact WLC, the first cell wiring layer 141 and the second cell wiring layer 143, and the first cell via 142 may include at least one of, for example, doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide, or a conductive metal oxide (e.g., PtO, RuO₂, IrO₂, SRO(SrRuO₃), BSRO((Ba,Sr)RuO₃), CRO(CaRuO₃), LSCo), but is not limited thereto, and may be variously changed.

According to embodiments, the channel pattern CH may include at least one of a single crystal semiconductor, a polycrystalline semiconductor, an oxide semiconductor, and a two-dimensional material. For example, a single crystal semiconductor may be single crystal silicon. As another example, the polycrystalline semiconductor may be polysilicon. As another example, the oxide semiconductor may be Indium Gallium Zinc Oxide (IGZO).

As another example, the two-dimensional material may be MoS₂, WS₂, MoSe₂ or WSe₂. However, the material included in the channel pattern CH is not limited thereto and may be changed in various ways.

According to embodiments, each of the interlayer dielectric layers ILD, the gate insulating film GI, the first cell insulating layer 130, and the second cell insulating layer 150 may include an insulating material. For example, the insulating material may include, but is not limited to, silicon oxide, silicon nitride, silicon oxynitride, and the like, and may be varied in various ways.

According to embodiments, the peripheral circuit structure PS may include a second substrate 200 and a peripheral circuit PC positioned over the second substrate 200.

According to embodiments, the second substrate 200 may include a third surface 200S1 and a fourth surface 200S2 facing one another. The peripheral circuit PC may be positioned on the third surface 200S1 of the second substrate 200. The peripheral circuit structure PS may be positioned on the cell structure CS such that the fourth surface 200S2 of the second substrate 200 faces the first surface 100S1 of the first substrate 100 of the cell structure CS in the third direction Z.

According to embodiments, the second substrate 200 may include a semiconductor material. For example, the second substrate 200 may include a group IV semiconductor, a group III-V compound semiconductor, a group II-VI compound semiconductor, etc. For example, the second substrate 200 may include a semiconductor such as Si, Ge, or a compound semiconductor such as SiGe, SiC, GaAs, InAs, or InP. For example, the second substrate 200 may be a single crystal epitaxial layer grown on a single crystal silicon substrate. However, the material of the second substrate 200 is not limited to this and may be changed in various ways.

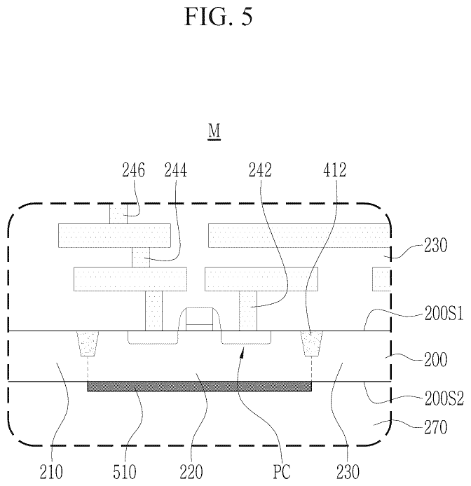

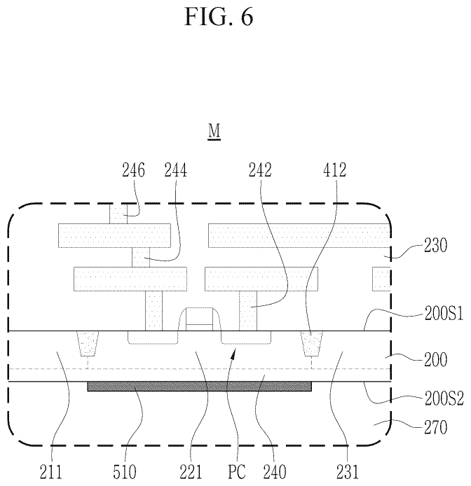

According to embodiments, the second substrate 200 may include first impurity regions described below and a second impurity region positioned between the first impurity regions. For example, the first impurity and the second impurity may be of different types. Specific details related to this are described later with reference to FIGS. 5 and 6.

According to embodiments, the peripheral circuit PC is a circuit that performs logical operations and may be composed of a combination of circuit elements such as transistors. The peripheral circuit PC may include circuitry that controls a plurality of memory cells MC positioned in the cell structure CS. For example, the peripheral circuit PC may include, but is not limited to, a row decoder that selects a row of a memory cell array based on an address signal, a column decoder that selects a column of the memory cell array based on the address signal, a sense amplifier that senses and amplifies data of a memory cell, and a word line driver that activates a word line of a selected row.

According to embodiments, the peripheral circuit PC may have a GAA (Gate All Around) structure, MBCFET™ (Multi Bridge Channel Field Effect Transistor) structure, etc., in which four sides of the channel are surrounded by gate electrodes. However, it is not limited to this, and the peripheral circuit PC may have a FinFET (Fin Field Effect Transistor) structure, a 3DSFET (3D Stack Field Effect Transistor) structure using next-generation technology, a CFET (Complementary Field Effect Transistor) structure, etc.

According to embodiments, the peripheral circuit structure PS may further include first and second peripheral insulating layers 230 and 250 sequentially laminated on a third surface 200S1 of a second substrate 200, first and second peripheral wiring layers 241 and 243 and first to third peripheral vias 242, 244 and 246 positioned within the first peripheral insulating layer 230, and a third peripheral wiring layer 260 positioned within the second peripheral insulating layer 250.

In FIG. 4, the peripheral circuit structure PS is illustrated as comprising first to third peripheral wiring layers 241, 243 and 260 and first to third peripheral vias 242, 244 and 246 connecting them, but the number of peripheral wiring layers and peripheral vias included in the peripheral circuit structure PS and/or the connection relationship thereof may be variously changed.

According to embodiments, the first and second peripheral wiring layers 241 and 243 may be positioned at different levels within the first peripheral insulating layer 230. The first peripheral wiring layer 241 is connected to at least one of a source region or a drain region of a peripheral circuit PC by a first peripheral via 242, and the first peripheral wiring layer 241 and the second peripheral wiring layer 243 may be connected to one another by a second peripheral via 244. The first and second peripheral wiring layers 241 and 243 and the first and second peripheral vias 242 and 244 may be surrounded by a first peripheral insulating layer 230.

According to embodiments, the third peripheral wiring layer 260 may be positioned within the second peripheral insulating layer 250. The third peripheral wiring layer 260 may be positioned on the upper surface of the first peripheral insulating layer 230. The third peripheral wiring layer 260 may be connected to the second peripheral wiring layer 243 by a third peripheral via 246 positioned within the first peripheral insulating layer 230. The third peripheral wiring layer 260 may be, for example, an input/output pad that connects the semiconductor device 10 to the outside. However, this is an example, and the function of the third peripheral wiring layer 260 may be changed in various ways.

According to embodiments, each of the first to third peripheral wiring layers 241, 243 and 260 and the first to third peripheral vias 242, 244 and 246 may include a conductive material. For example, each of the first to third peripheral wiring layers 241, 243 and 260 and the first to third peripheral vias 242, 244 and 246 may include the same conductive material as the first cell wiring layer 141, the second cell wiring layer 143, and the first cell via 142. However, this is exemplary, and the materials included in the first to third peripheral wiring layers 241, 243 and 260 and the first to third peripheral vias 242, 244 and 246 may be variously changed.

According to embodiments, the first and second peripheral insulating layers 230 and 250 may include an insulating material. For example, the insulating material may include, but is not limited to, silicon oxide, and may be varied in various ways.

The cell structure CS of the semiconductor device 10 according to embodiments may further include a cell buffer layer 170 positioned on a second cell insulating layer 150, and the peripheral circuit structure PS may further include a first peripheral buffer layer 270 positioned below a fourth surface 200S2 of the second substrate 200.

According to embodiments, the cell buffer layer 170 may include an insulating material. For example, the insulating material may include, but is not limited to, silicon oxide, and may be varied in various ways.

According to embodiments, the first peripheral buffer layer 270 may include an insulating material. According to embodiments, the first peripheral buffer layer 270 may have unique charge characteristics depending on the formation process and thermal conditions.

According to embodiments, the first peripheral buffer layer 270 may include a material having a positive charge. For example, the first peripheral buffer layer 270 may include Tetraethyl Orthosilicate (TEOS). However, it is not limited thereto, and the first peripheral buffer layer 270 may include various materials having a positive charge.

More specifically, the first peripheral buffer layer 270 may capture holes or have fixed positive charges due to defects or imperfect bonding structures within the film. When the first peripheral buffer layer 270 comes into contact with the second substrate 200, if the first peripheral buffer layer 270 becomes positively charged, a negative charge may be induced in the second substrate 200 in response. This charge distribution may cause leakage current by forming an unintended current path within the second substrate 200.

A semiconductor device 10 according to embodiments may include a first charge shielding layer 510 positioned between a fourth surface 200S2 of a second substrate 200 and a first peripheral buffer layer 270. For example, a semiconductor device 10 according to embodiments may include a first charge shielding layer 510 to suppress a phenomenon in which negative charges are induced in a second substrate 200 by positive charges induced in a first peripheral buffer layer 270.

According to embodiments, the first charge shielding layer 510 may be positioned between the first substrate 100 of the cell structure CS and the second substrate 200 of the peripheral circuit structure PS. The first charge shielding layer 510 may be positioned between the first surface 100S1 of the first substrate 100 and the fourth surface 200S2 of the second substrate 200. For example, the first charge shielding layer 510 may be positioned between the memory cell layer MSL of the cell structure CS and the fourth surface 200S2 of the second substrate 200 of the peripheral circuit structure PS.

According to embodiments, the first charge shielding layer 510 may be positioned in the peripheral circuit structure PS. The first charge shielding layer 510 may be positioned between the second substrate 200 and the first peripheral buffer layer 270. Alternatively, the first charge shielding layer 510 may be described as being positioned within the first peripheral buffer layer 270.

According to embodiments, the first charge shielding layer 510 covers at least a portion of the fourth surface 200S2 of the second substrate 200 and may be in contact with the fourth surface 200S2 of the second substrate 200. However, it is not limited thereto, and another layer may be additionally positioned between the fourth surface 200S2 of the second substrate 200 and the first charge shielding layer 510 and between the first peripheral buffer layer 270 and the first charge shielding layer 510.

According to embodiments, the thickness of the first charge shielding layer 510 may be thinner than the thicknesses of the cell buffer layer 170, the second substrate 200, and the first peripheral buffer layer 270. However, this is an example, and the position and/or thickness of the first charge shielding layer 510 may be changed in various ways.

According to embodiments, the first charge shielding layer 510 may include at least one of single crystal silicon, polycrystalline silicon, or amorphous silicon. Specific details related to the first charge shielding layer 510 will be described in detail later with reference to FIGS. 5 and 6.

A semiconductor device 10 according to embodiments may further include a first bonding layer 175 positioned above the cell buffer layer 170 and a second bonding layer 275 positioned below the first peripheral buffer layer 270.

According to embodiments, the first bonding layer 175 and the second bonding layer 275 may be in contact with one another. The first bonding layer 175 and the second bonding layer 275 may be in contact with one another to form a boundary surface BS. The cell structure CS and the peripheral circuit structure PS may be bonded to one another through the first bonding layer 175 and the second bonding layer 275. In FIG. 4, the semiconductor device 10 is illustrated as comprising a cell buffer layer 170, a first bonding layer 175, a second bonding layer 275, and a first peripheral buffer layer 270 that are sequentially stacked, but the number of buffer layers and bonding layers included in the semiconductor device 10 and/or their order may be variously changed.

A semiconductor device 10 according to embodiments may further include a through via 400 connecting a peripheral circuit structure PS and a cell structure CS and a first insulating pattern 410 surrounding the through via.

According to embodiments, the through via 400 may extend along the third direction Z from the peripheral circuit structure PS to the cell structure CS. Some of the through vias 400 may be single through vias, with some positioned in the cell structure CS and others positioned in the peripheral circuit structure PS. In other words, a single through via 400 may penetrate at least a portion of the first peripheral insulating layer 230, the first insulating pattern 410, the first peripheral buffer layer 270, the cell buffer layer 170, and at least a portion of the second cell insulating layer 150.

According to embodiments, a through via 400 may connect a cell wiring layer connected to a plurality of memory cells MC positioned in a cell structure CS and a peripheral wiring layer connected to a peripheral circuit PC positioned in a peripheral circuit structure PS. For example, a through via 400 may connect a second cell wiring layer 143 positioned in a cell structure CS and a second peripheral wiring layer 243 positioned in a peripheral circuit structure PS.

In FIG. 4, one end of the through via 400 is illustrated as being connected to the second cell wiring layer 143 and the other end is illustrated as being connected to the second peripheral wiring layer 243, but the connection relationship between the through via 400, the cell wiring layer, and the peripheral wiring layer is not limited thereto and may be changed in various ways. For example, one end of the through via 400 may be connected to a plurality of first cell wiring layers 141 positioned in the cell structure CS, and the other end may be connected to a first peripheral wiring layer 241 positioned in the peripheral circuit structure PS. As another example, a through via 400 may be composed of the plurality of vias to connect a cell structure CS and a peripheral circuit structure PS.

In embodiments, the through via 400 may have a pillar shape in cross section. For example, the through via 400 may have an inclined side surface so that the width becomes narrower as it approaches the first substrate 100 according to the aspect ratio in the cross section. However, the cross-sectional shape of the through via 400 is not limited to this and may be changed in various ways.

According to embodiments, the first insulating pattern 410 may be positioned within the second substrate 200. The first insulating pattern 410 is positioned between the through via 400 and the second substrate 200, and may surround a side of the through via 400 penetrating the second substrate 200. The through via 400 and the second substrate 200 may be insulated by the first insulating pattern 410.

According to embodiments, the first insulating pattern 410 may have a shape penetrating the second substrate 200. The first insulating pattern 410 may be formed by filling an insulating material in a trench that is deeper than the isolation pattern 412 described later. The height of the first insulating pattern 410 along the third direction Z may be the same as the thickness of the second substrate 200 along the third direction Z. In other words, the upper surface of the first insulating pattern 410 may be positioned at substantially the same level as the third surface 200S1 of the second substrate 200, and the lower surface of the first insulating pattern 410 may be positioned at substantially the same level as the fourth surface 200S2 of the second substrate 200. The first insulating pattern 410 may have a shape in which the width becomes narrower from the third surface 200S1 of the second substrate 200 to the fourth surface 200S2. In other words, the first insulating pattern 410 may have a maximum width at the upper surface and a minimum width at the lower surface.

In embodiments, the through via 400 may include a conductive material. For example, the through via 400 may include the same conductive material as the first cell via 142 and the first to third peripheral vias 242, 244 and 246 described above.

According to embodiments, the first insulating pattern 410 may include an insulating material. For example, the first insulating pattern 410 may include silicon oxide. However, it is not limited thereto, and the material included in the first insulating pattern 410 may be changed in various ways.

According to embodiments, a device isolation pattern 412 may be positioned within the second substrate 200. The isolation pattern 412 may be formed by filling an insulating material in a trench having a predetermined depth from the upper surface of the second substrate 200. The isolation pattern 412 may include, for example, silicon oxide, but is not limited thereto. The insulating material included in the isolation pattern 412 may be varied in various ways.

According to embodiments, the isolation pattern 412 may have a shallower depth from the upper surface of the second substrate 200 than the first insulating pattern 410. The lower surface of the separation pattern 412 may be positioned at a higher level than the lower surface of the second substrate 200.

According to embodiments, the active area of the second substrate 200 may be defined by the isolation pattern 412. A plurality of separation patterns 412 may be spaced in a parallel direction on the upper surface of the second substrate 200. The region of the second substrate 200 between the plurality of isolation patterns 412 may be defined as an active region. The peripheral circuit PC may be formed in the active area of the second substrate 200.

Hereinafter, semiconductor devices according to various embodiments will be described with reference to FIGS. 5 and 6. In the embodiments below, the same components as those described previously are referred to by the same reference numerals, and redundant descriptions may be omitted or simplified.

FIGS. 5 and 6 are enlarged views of region M of FIG. 4 according to some embodiments.

Referring to FIG. 5, the second substrate 200 may include first impurity regions 210 and 230 and a second impurity region 220 positioned between the first impurity regions 210 and 230. In other words, first impurity regions 210 and 230 may be positioned on both sides of the second impurity region 220.

According to embodiments, the first impurity regions 210 and 230 and the second impurity region 220 may include different impurities. For example, the first impurity included in the first impurity regions 210 and 230 may be n-type, and the second impurity included in the second impurity region 220 may be p-type. In other words, the first impurity regions 210 and 230 may be regions doped with n-type impurities, and the second impurity region 220 may be regions doped with p-type impurities. The first impurity regions 210 and 230 may include P, Sb, As, or a combination thereof. The second impurity region 220 may include B, V, In, Ga, Al, or a combination thereof.

According to embodiments, the first peripheral buffer layer 270 positioned below the second substrate 200 may include a material having a positive charge. For example, the first peripheral buffer layer 270 may include Tetraethyl Orthosilicate (TEOS). However, it is not limited thereto, and the first peripheral buffer layer 270 may include various materials having a positive charge.

More specifically, the first peripheral buffer layer 270 may capture holes or have fixed positive charges due to defects or imperfect bonding structures within the film. When the first peripheral buffer layer 270 comes into contact with the second substrate 200, if the first peripheral buffer layer 270 becomes positively charged, a negative charge may be induced in the second substrate 200 in response.

Specifically, since the first peripheral buffer layer 270 adjacent to the second substrate 200 has a positive charge, an area of the second substrate 200 adjacent to the first peripheral buffer layer 270 may have a negative charge. This charge distribution may cause leakage current by forming an unintended current path within the second substrate 200.

A semiconductor device 10 according to embodiments may include a first charge shielding layer 510 to suppress a phenomenon in which negative charges are induced in a second substrate 200 by positive charges induced in a first peripheral buffer layer 270.

According to embodiments, a first charge shielding layer 510 may be positioned on a fourth surface 200S2 of a second substrate 200. According to embodiments, the first charge shielding layer 510 may overlap the second impurity region 220 in the third direction Z. At this time, the first charge shielding layer 510 may not overlap the first impurity regions 210 and 230 in the third direction Z. However, the first charge shielding layer 510 does not have to overlap with the first impurity regions 210 and 230 in the third direction Z, and the first charge shielding layer 510 may overlap with at least a portion of the first impurity regions 210 and 230 in the third direction Z.

According to embodiments, the first charge shielding layer 510 may be in contact with the fourth surface 200S2 of the second substrate 200. According to embodiments, the first charge shielding layer 510 may cover a second impurity region 220 positioned between the first impurity regions 210 and 230. For example, the first charge shielding layer 510 may cover only the second impurity region 220, or may cover part of the region adjacent to the second impurity region 220.

According to embodiments, the first charge shielding layer 510 may include at least one of single crystal silicon, polycrystalline silicon, or amorphous silicon. For example, the first charge shielding layer 510 may include Si doped with boron (B) or SiGe doped with boron (B).

Referring to FIG. 6, a semiconductor device according to embodiments may include eleventh impurity regions 211 and 231 and a twenty-first impurity region 221 positioned between the eleventh impurity regions 211 and 231. According to embodiments, the semiconductor device may further include a third impurity region 240 positioned below the eleventh impurity regions 211 and 231 and the twenty-first impurity region 221. According to embodiments, the third impurity region 240 may include the same type of impurity as the eleventh impurity regions 211 and 231 and a different type of impurity than the twenty-first impurity region 221. For example, the eleventh impurity regions 211 and 231 and the third impurity region 240 may include n-type impurities, and the twenty-first impurity region 221 may include p-type impurities. In other words, the eleventh impurity included in the eleventh impurity regions 211 and 231 and the third impurity included in the third impurity region 240 may be n-type, and the twenty-first impurity included in the twenty-first impurity region 221 may be p-type.

According to embodiments, the third impurity region 240 may entirely cover the eleventh impurity regions 211 and 231 and the twenty-first impurity region 221. However, it is not limited thereto, and may cover at least a portion of the eleventh impurity regions 211 and 231 and/or at least a portion of the twenty-first impurity region 221.

According to embodiments, a first charge shielding layer 510 may be positioned on a fourth surface 200S2 of a second substrate 200. According to embodiments, the first charge shielding layer 510 may overlap the twenty-first impurity region 221 in the third direction Z. At this time, the first charge shielding layer 510 may not overlap with the eleventh impurity regions 211 and 231.

According to embodiments, the first charge shielding layer 510 may be in contact with the fourth surface 200S2 of the second substrate 200. According to embodiments, the first charge shielding layer 510 may cover a third impurity region 240 that overlaps the twenty-first impurity region 221.

According to embodiments, the first charge shielding layer 510 may include at least one of single crystal silicon, polycrystalline silicon, or amorphous silicon. For example, the first charge shielding layer 510 may include Si doped with boron (B) or SiGe doped with boron (B).

As described above, the semiconductor device according to the present disclosure may reduce leakage current by comprising a silicon layer doped with boron (B) as the first charge shielding layer 510 to suppress the phenomenon in which negative charges are induced in the second substrate 200 by positive charges induced in the first peripheral buffer layer 270.

In other words, the silicon layer doped with boron, a group 3 impurity, may suppress charge induction by positive charges of the first peripheral buffer layer 270 and prevent the creation of a leakage path by forming a potential barrier on the band structure.

In addition, as described above, the first charge shielding layer 510 of the semiconductor device according to the present disclosure may reduce the occurrence of leakage current within the second substrate 200 by suppressing the influence of an electric field induced by fixed charges due to the first peripheral buffer layer 270 having a positive charge.

In addition, as described above, the first charge shielding layer 510 of the semiconductor device according to the present disclosure may prevent an unintended current path from being formed inside the second substrate 200 by shielding the positive charge influence generated from the first peripheral buffer layer 270.

In addition, as described above, the first charge shielding layer 510 may prevent accumulation of charges (electrons) of opposite polarity induced by the fixed charges of the first peripheral buffer layer 270, thereby alleviating potential imbalance within the second substrate 200.

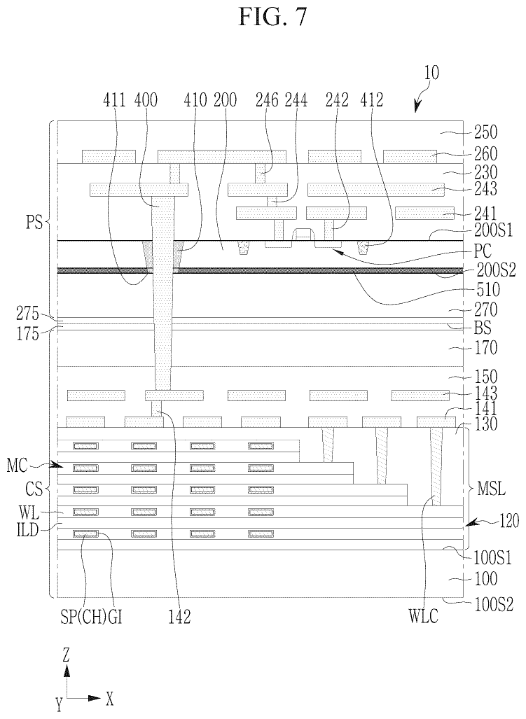

FIG. 7 is a cross-sectional view of a semiconductor device according to embodiments.

The semiconductor device illustrated in FIG. 7 may include components similar to or identical to the semiconductor devices described with reference to FIGS. 1 to 6. However, the semiconductor device in this embodiment has a structure in which the first charge shielding layer 510 is positioned entirely on the second substrate 200, unlike that illustrated in FIGS. 1 to 6. Here, any overlapping content from the above will be briefly explained or omitted, and the differences will be explained primarily.

Referring to FIG. 7, a semiconductor device according to embodiments may include a first peripheral buffer layer 270 positioned below a second substrate 200. According to embodiments, the first peripheral buffer layer 270 may include a material having a positive charge. For example, the first peripheral buffer layer 270 may include Tetraethyl Orthosilicate (TEOS). However, it is not limited thereto, and the first peripheral buffer layer 270 may include various materials having a positive charge.

According to embodiments, a first charge shielding layer 510 may be positioned on a fourth surface 200S2 of a second substrate 200. According to embodiments, the first charge shielding layer 510 may be positioned entirely on the fourth surface 200S2 of the second substrate 200. Specifically, the first charge shielding layer 510 may be in full contact with the fourth surface 200S2 of the second substrate 200. According to embodiments, the first charge shielding layer 510 may cover the first impurity regions 210 and 230 and the second impurity region 220 illustrated in FIG. 5. According to embodiments, the first charge shielding layer 510 may cover a third impurity region 240 that overlaps with the eleventh impurity regions 211 and 231 and the twenty-first impurity region 221 illustrated in FIG. 6.

According to embodiments, the first charge shielding layer 510 may include at least one of single crystal silicon, polycrystalline silicon, or amorphous silicon. For example, the first charge shielding layer 510 may include Si doped with boron (B) or SiGe doped with boron (B).

According to embodiments, the semiconductor device may further include a second insulating pattern 411 positioned between the first charge shielding layer 510 and the through via 400.

According to embodiments, the second insulating pattern 411 is positioned between the through via 400 and the first charge shielding layer 510 and may surround a side surface of the through via 400 penetrating the first charge shielding layer 510. The through via 400 and the first charge shielding layer 510 may be insulated by the second insulating pattern 411.

According to embodiments, the second insulating pattern 411 may have a shape penetrating the first charge shielding layer 510. The height along the third direction Z of the second insulating pattern 411 may be the same as the thickness along the third direction Z of the first charge shielding layer 510. In other words, the upper surface of the second insulating pattern 411 may be positioned at substantially the same level as the upper surface of the first charge shielding layer 510, and the lower surface of the second insulating pattern 411 may be positioned at substantially the same level as the lower surface of the first charge shielding layer 510.

According to embodiments, the second insulating pattern 411 may have a shape whose width becomes narrower from the upper surface to the lower surface of the first charge shielding layer 510. In other words, the second insulating pattern 411 may have a maximum width at the upper surface and a minimum width at the lower surface. However, it is not limited to this, and the shape of the second insulating pattern 411 may be changed in various ways.

According to embodiments, the second insulating pattern 411 may include an insulating material. For example, the second insulating pattern 411 may include silicon oxide. However, it is not limited thereto, and the material included in the second insulating pattern 411 may be changed in various ways.

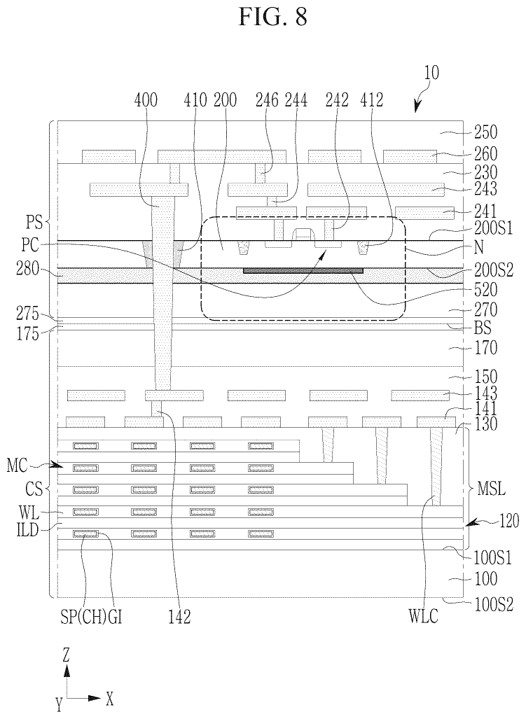

FIG. 8 is a cross-sectional view of a semiconductor device according to embodiments.

The semiconductor device 10 illustrated in FIG. 8 may include components similar to or identical to the semiconductor devices described with reference to FIGS. 1 to 7. However, the semiconductor device in this embodiment has a structure that, unlike that illustrated in FIGS. 1 to 7, further comprises a second peripheral buffer layer 280 positioned over the first peripheral buffer layer 270 and a second charge shielding layer 520 positioned between the second peripheral buffer layer 280 and the second substrate 200. Here, any overlapping content from the above will be briefly explained or omitted, and the differences will be explained primarily.

According to embodiments, the cell structure CS of the semiconductor device 10 may further include a cell buffer layer 170 positioned on a second cell insulating layer 150, and the peripheral circuit structure PS may include a first peripheral buffer layer 270 and a second peripheral buffer layer 280 positioned below a fourth surface 200S2 of the second substrate 200.

According to embodiments, the first peripheral buffer layer 270 may include an insulating material. According to embodiments, the first peripheral buffer layer 270 may have unique charge characteristics depending on the formation process and thermal conditions.

According to embodiments, the first peripheral buffer layer 270 may include a material having a positive charge. For example, the first peripheral buffer layer 270 may include Tetraethyl Orthosilicate (TEOS). However, it is not limited thereto, and the first peripheral buffer layer 270 may include various materials having a positive charge.

According to embodiments, the second peripheral buffer layer 280 may be positioned between the fourth surface 200S2 of the second substrate 200 and the first peripheral buffer layer 270. One side of the second peripheral buffer layer 280 may be in contact with the fourth surface 200S2 of the second substrate 200, and the other side of the second peripheral buffer layer 280 may be in contact with the first peripheral buffer layer 270.

According to embodiments, the second peripheral buffer layer 280 may include an insulating material. According to embodiments, the second peripheral buffer layer 280 may have unique charge characteristics depending on the formation process and thermal conditions.

According to embodiments, the second peripheral buffer layer 280 may include a material having a negative charge. This negative charge may be due to fixed charges within the membrane or to the properties of the bonding structure. For example, the second peripheral buffer layer 280 may include aluminum oxide (AlxOy). However, it is not limited thereto, and the second peripheral buffer layer 280 may include various materials having a negative charge.

In this way, when the second peripheral buffer layer 280 is negatively charged, a positive charge may be induced in the second substrate 200, which may cause leakage current by forming an unintended current path.

Specifically, since the second peripheral buffer layer 280 adjacent to the second substrate 200 has a negative charge, the second substrate 200 adjacent to the second peripheral buffer layer 280 may have a positive charge. This charge distribution may cause leakage current by forming an unintended current path within the second substrate 200.

A semiconductor device 10 according to embodiments may further include a second charge shielding layer 520 positioned between the fourth surface 200S2 of the second substrate 200 and the second peripheral buffer layer 280.

According to embodiments, the second charge shielding layer 520 may be positioned between the first substrate 100 of the cell structure CS and the second substrate 200 of the peripheral circuit structure PS. The second charge shielding layer 520 may be positioned between the first surface 100S1 of the first substrate 100 and the fourth surface 200S2 of the second substrate 200. For example, the second charge shielding layer 520 may be positioned between the memory cell layer MSL of the cell structure CS and the fourth surface 200S2 of the second substrate 200 of the peripheral circuit structure PS.

According to embodiments, the second charge shielding layer 520 may be positioned in the peripheral circuit structure PS. The second charge shielding layer 520 may be positioned between the second substrate 200 and the second peripheral buffer layer 280. Alternatively, the second charge shielding layer 520 may be described as being positioned within the second peripheral buffer layer 280.

According to embodiments, the second charge shielding layer 520 covers at least a portion of the fourth surface 200S2 of the second substrate 200 and may be in contact with the fourth surface 200S2 of the second substrate 200. However, it is not limited thereto, and another layer may be additionally positioned between the fourth surface 200S2 of the second substrate 200 and the second charge shielding layer 520 and between the second peripheral buffer layer 280 and the second charge shielding layer 520.

In embodiments, the thickness of the second charge shielding layer 520 may be thinner than the thicknesses of the cell buffer layer 170, the second substrate 200, and the second peripheral buffer layer 280. However, this is an example, and the position and/or thickness of the second charge shielding layer 520 may be changed in various ways.

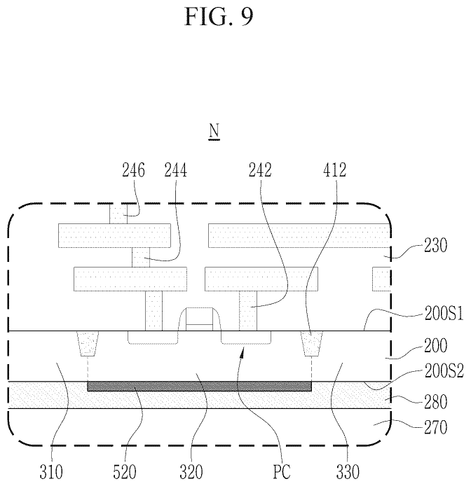

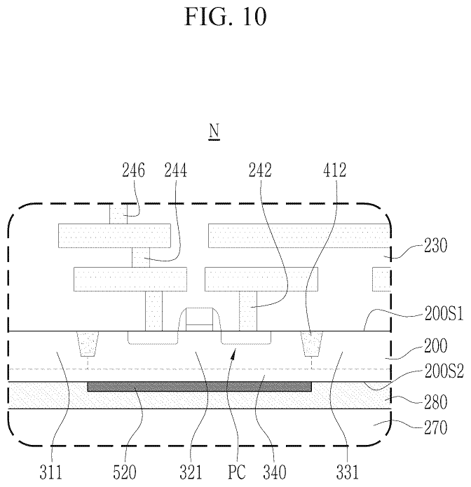

According to embodiments, the second charge shielding layer 520 may include at least one of single crystal silicon, polycrystalline silicon, or amorphous silicon. Specific details related to the second charge shielding layer 520 will be described in detail later with reference to FIGS. 9 and 10.

Hereinafter, semiconductor devices according to various embodiments will be described with reference to FIGS. 9 and 10. In the embodiments below, the same components as those described previously are referred to by the same reference numerals, and redundant descriptions may be omitted or simplified.

FIGS. 9 and 10 are enlarged views of region N of FIG. 8 according to some embodiments.

Referring to FIG. 9, the second substrate 200 may include fourth impurity regions 310 and 330 and a fifth impurity region 320 positioned between the fourth impurity regions 310 and 330. In other words, fourth impurity regions 310 and 330 may be positioned on both sides of the fifth impurity region 320.

According to embodiments, the fourth impurity regions 310 and 330 and the fifth impurity region 320 may include different impurities. For example, the fourth impurity may be p-type and the fifth impurity may be n-type. In other words, the fourth impurity regions 310 and 330 may be regions doped with p-type impurities, and the fifth impurity region 320 may be regions doped with n-type impurities. The fourth impurity regions 310 and 330 may include B, V, In, Ga, Al, or a combination thereof. The fifth impurity region 320 may include P, Sb, As, or a combination thereof.

According to embodiments, the second peripheral buffer layer 280 positioned below the second substrate 200 may include a material having a negative charge. For example, the second peripheral buffer layer 280 may include aluminum oxide (AlxOy). However, it is not limited thereto, and the second peripheral buffer layer 280 may include various materials having a negative charge.

According to embodiments, when the second peripheral buffer layer 280 comes into contact with the second substrate 200, if the second peripheral buffer layer 280 becomes negatively charged, a positive charge may be induced in the second substrate 200 in response thereto.

Specifically, since the second peripheral buffer layer 280 adjacent to the second substrate 200 has a negative charge, an area of the second substrate 200 adjacent to the second peripheral buffer layer 280 may have a positive charge. This charge distribution may cause leakage current by forming an unintended current path within the second substrate 200.

A semiconductor device 10 according to embodiments may include a second charge shielding layer 520 to suppress a phenomenon in which positive charges are induced in a second substrate 200 by negative charges induced in a second peripheral buffer layer 280.

According to embodiments, a second charge shielding layer 520 may be positioned on the fourth surface 200S2 of the second substrate 200. According to embodiments, the second charge shielding layer 520 may overlap the fifth impurity region 320 in the third direction Z. At this time, the second charge shielding layer 520 may not overlap with the fourth impurity regions 310 and 330 in the third direction Z. However, the second charge shielding layer 520 does not have to overlap with the fourth impurity regions 310 and 330 in the third direction Z, and the second charge shielding layer 520 may overlap with at least a portion of the fourth impurity regions 310 and 330 in the third direction Z.

According to embodiments, the second charge shielding layer 520 may be in contact with the fourth surface 200S2 of the second substrate 200. According to embodiments, the second charge shielding layer 520 may cover the fifth impurity region 320 positioned between the fourth impurity regions 310 and 330. For example, the second charge shielding layer 520 may cover only the fifth impurity region 320, or may cover part of the region adjacent to the fifth impurity region 320.

According to embodiments, the second charge shielding layer 520 may include at least one of single crystal silicon, polycrystalline silicon, or amorphous silicon. For example, the second charge shielding layer 520 may include Si doped with phosphorus (P), SiGe doped with phosphorus (P), Si doped with arsenic (As), or SiGe doped with arsenic (As).

Referring to FIG. 10, a semiconductor device according to embodiments may include a forty-first impurity regions 311 and 331 and a fifty-first impurity region 321 positioned between the forty-first impurity regions 311 and 331. According to embodiments, the semiconductor device may further include a sixth impurity region 340 positioned below the forty-first impurity regions 311 and 331 and the fifty-first impurity region 321. According to embodiments, the sixth impurity region 340 may include the same type of impurity as the forty-first impurity regions 311 and 331 and may include a different type of impurity than the fifth impurity region. For example, the forty-first impurity regions 311 and 331 and the sitxh impurity region 340 may include p-type impurities, and the fifty-first impurity region 321 may include n-type impurities. In other words, the forty-first impurity included in the forty-first impurity regions 311 and 331 and the sitxh impurity included in the sitxh impurity region 340 may be p-type, and the fifty-first impurity included in the fifty-first impurity region 321 may be n-type.

According to embodiments, the sixth impurity region 340 may entirely cover the forty-first impurity regions 311 and 331 and the fifty-first impurity region 321. However, it is not limited thereto, and may cover at least a portion of the forty-first impurity regions 311 and 331 and/or at least a portion of the fifty-first impurity region 321.

According to embodiments, a second charge shielding layer 520 may be positioned on the fourth surface 200S2 of the second substrate 200. According to embodiments, the second charge shielding layer 520 may overlap the fifty-first impurity region 321 in the third direction Z. At this time, the second charge shielding layer 520 may not overlap with the forty-first impurity regions 311 and 331.

According to embodiments, the second charge shielding layer 520 may be in contact with the fourth surface 200S2 of the second substrate 200. In embodiments, the second charge shielding layer 520 may cover the sixth impurity region 340 overlapping the fifty-first impurity region 321.

According to embodiments, the second charge shielding layer 520 may include at least one of single crystal silicon, polycrystalline silicon, or amorphous silicon. For example, the second charge shielding layer 520 may include Si doped with phosphorus (P), SiGe doped with phosphorus (P), Si doped with arsenic (As), or SiGe doped with arsenic (As).

As described above, the semiconductor device according to the present disclosure may reduce leakage current by comprising a silicon layer doped with phosphorus or arsenic (As) the second charge shielding layer 520 to suppress the phenomenon in which positive charges are induced in the second substrate 200 by negative charges induced in the second peripheral buffer layer 280.

In other words, the silicon layer doped with phosphorus or arsenic, which are Group 5 impurities, may suppress the inflow of holes induced by the negative charge of the second peripheral buffer layer 280 and prevent the creation of a leakage path by forming a potential barrier on the band structure.

In addition, as described above, the second charge shielding layer 520 of the semiconductor device according to the present disclosure may reduce the occurrence of leakage current within the second substrate 200 by suppressing the influence of an electric field induced by fixed charges due to the second peripheral buffer layer 280 having a negative charge.

In addition, as described above, the second charge shielding layer 520 of the semiconductor device according to the present disclosure may prevent an unintended current path from being formed inside the second substrate 200 by shielding the negative charge influence generated from the second peripheral buffer layer 280.

In addition, as described above, the second charge shielding layer 520 may prevent the accumulation of charges (holes) of opposite polarity induced by the fixed charges of the second peripheral buffer layer 280, thereby alleviating the potential imbalance within the second substrate 200.

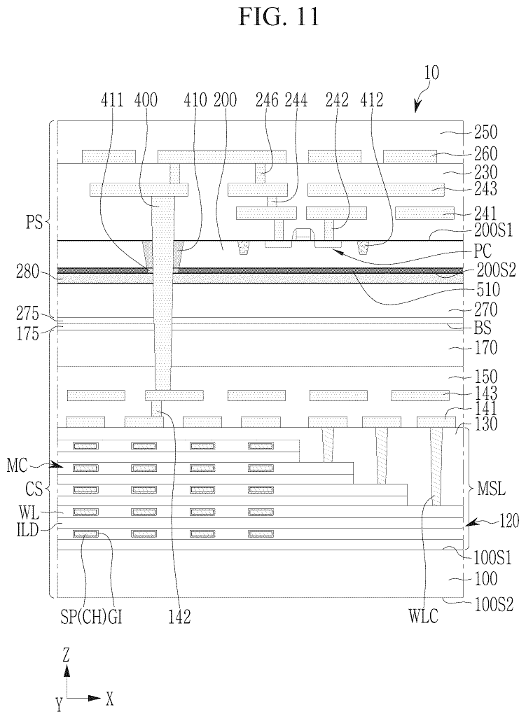

FIG. 11 is a cross-sectional view of a semiconductor device according to embodiments.

The semiconductor device illustrated in FIG. 11 may include components similar to or identical to the semiconductor devices described with reference to FIGS. 8 to 10. However, the semiconductor device in this embodiment has a structure in which the second charge shielding layer 520 is positioned entirely on the second substrate 200, unlike that illustrated in FIGS. 8 to 10. Here, any overlapping content from the above will be briefly explained or omitted, and the differences will be explained primarily.

Referring to FIG. 11, a semiconductor device according to embodiments may include a second peripheral buffer layer 280 positioned below a second substrate 200. According to embodiments, the second peripheral buffer layer 280 may include a material having a negative charge. For example, the second peripheral buffer layer 280 may include aluminum oxide (AlxOy). However, it is not limited thereto, and the second peripheral buffer layer 280 may include various materials having a negative charge.

According to embodiments, a second charge shielding layer 520 may be positioned on the fourth surface 200S2 of the second substrate 200. According to embodiments, the second charge shielding layer 520 may be positioned entirely on the fourth surface 200S2 of the second substrate 200. Specifically, the second charge shielding layer 520 may be in full contact with the fourth surface 200S2 of the second substrate 200. According to embodiments, the second charge shielding layer 520 may cover the fourth impurity regions 310 and 330 and the fifth impurity region 320 illustrated in FIG. 9. According to embodiments, the second charge shielding layer 520 may cover the sixth impurity region 340 overlapping with the forty-first impurity regions 311 and 331 and the fifty-first impurity region 321 illustrated in FIG. 10.

According to embodiments, the second charge shielding layer 520 may include at least one of single crystal silicon, polycrystalline silicon, or amorphous silicon. For example, the second charge shielding layer 520 may include Si doped with phosphorus (P), SiGe doped with phosphorus (P), Si doped with arsenic (As), or SiGe doped with arsenic (As).

According to embodiments, the semiconductor device may further include a second insulating pattern 411 positioned between the second charge shielding layer 520 and the through via 400.

According to embodiments, the second insulating pattern 411 is positioned between the through via 400 and the second charge shielding layer 520 and may surround a side surface of the through via 400 penetrating the second charge shielding layer 520. The through via 400 and the second charge shielding layer 520 may be insulated by the second insulating pattern 411.

According to embodiments, the second insulating pattern 411 may have a shape penetrating the second charge shielding layer 520. The height of the second insulating pattern 411 along the third direction Z may be the same as the thickness of the second charge shielding layer 520 along the third direction Z. In other words, the upper surface of the second insulating pattern 411 may be positioned at substantially the same level as the upper surface of the second charge shielding layer 520, and the lower surface of the second insulating pattern 411 may be positioned at substantially the same level as the lower surface of the second charge shielding layer 520.

According to embodiments, the second insulating pattern 411 may have a shape whose width becomes narrower from the upper surface to the lower surface of the second charge shielding layer 520. In other words, the second insulating pattern 411 may have a maximum width at the upper surface and a minimum width at the lower surface. However, it is not limited to this, and the shape of the second insulating pattern 411 may be changed in various ways.

According to embodiments, the second insulating pattern 411 may include an insulating material. For example, the second insulating pattern 411 may include silicon oxide. However, it is not limited thereto, and the material included in the second insulating pattern 411 may be changed in various ways.

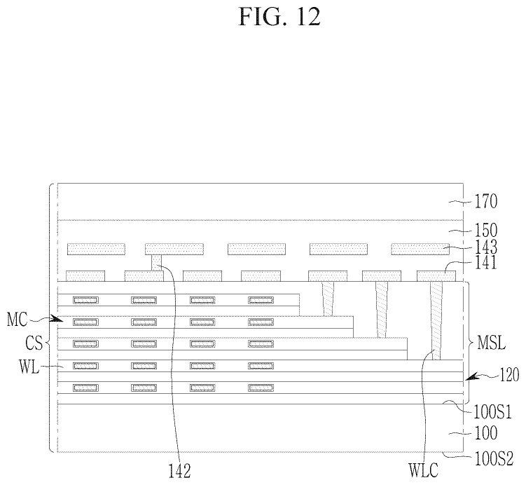

Hereinafter, a method for manufacturing the semiconductor device of FIG. 4 will be described with reference to FIGS. 12 to 18.

FIGS. 12 to 18 are intermediate step drawings for explaining a method of manufacturing a semiconductor device according to embodiments.

Referring to FIG. 12, a cell structure CS may be formed.

According to embodiments, a memory cell layer MSL may be laminated on a first surface 100S1 of a first substrate 100 to form a cell structure CS. A memory cell layer MSL may include a plurality of memory cells MC, bit lines (e.g., bit lines BL of FIG. 3) and word lines WL connected to the plurality of memory cells MC, and contacts (e.g., bit line contacts (not shown) and word line contacts WLC connecting the bit lines BL and word lines WL to a first cell wiring layer 141. It may be assumed that the plurality of memory cells MC included in the memory cell layer MSL of FIG. 12 are the same as the plurality of memory cells MC in the embodiments of FIGS. 2 and 4. Accordingly, the contents described above with reference to FIGS. 2 and 4 may be equally applied to the plurality of memory cells MC.

According to embodiments, a first cell wiring layer 141 and a second cell wiring layer 143 may be formed on a memory cell layer MSL. For example, a metal layer may be formed on a memory cell layer MSL, and the metal layer may be patterned to form a first cell wiring layer 141 and a second cell wiring layer 143. An insulating material layer covering the first cell wiring layer 141 and the second cell wiring layer 143 may be formed, and a first cell via 142 connected to the first cell wiring layer 141 may be formed by penetrating the insulating material layer in a third direction Z perpendicular to the first surface 100S1 of the first substrate 100. Through the above-described process, a first cell wiring layer 141 and a second cell wiring layer 143 comprising a plurality of wiring layers, a first cell via 142 connecting the plurality of wiring layers in a third direction Z, and a second cell insulation layer 150 surrounding the first cell wiring layer 141, the second cell wiring layer 143, and the first cell via 142 may be formed.

According to embodiments, a cell buffer layer 170 covering the second cell insulation layer 150 may be formed. According to embodiments, the cell buffer layer 170 may include an insulating material. For example, the insulating material may include, but is not limited to, silicon oxide, and may be varied in various ways.

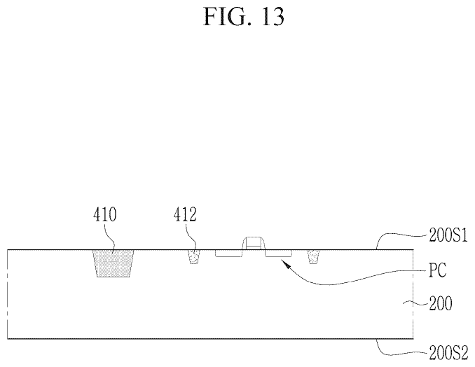

Referring to FIG. 13, a peripheral circuit PC may be formed on the third surface 200S1 of the second substrate 200. Peripheral circuits PC are circuits that perform logical operations and may be composed of a combination of circuit elements such as transistors.

In embodiments, the peripheral circuit PC may include circuitry that controls a plurality of memory cells. For example, the peripheral circuit PC may include, but is not limited to, a row decoder that selects a row of a memory cell array based on an address signal, a column decoder that selects a column of the memory cell array based on the address signal, a sense amplifier that senses and amplifies data of a memory cell, and a word line driver that activates a word line of a selected row.

In embodiments, the peripheral circuit PC may include at least one of an arithmetic circuit that performs arithmetic using data stored in a plurality of memory cells and a buffer that temporarily stores data used in the arithmetic circuit. For example, the computational circuit may be an NPU, and the buffer may be a cache memory of the NPU, but is not limited thereto.

According to embodiments, a first insulating pattern 410 may be formed inside a second substrate 200. For example, a sunken trench may be formed from the third surface 200S1 of the second substrate 200 toward the fourth surface 200S2, and an insulating material may be filled in the trench to form a first insulating pattern 410.

According to embodiments, the first insulating pattern 410 may have a shape whose width becomes narrower from the third surface 200S1 of the second substrate 200 to the fourth surface 200S2. The first insulating pattern 410 may include one side positioned at substantially the same level as the third surface 200S1 of the second substrate 200 and the other side facing the one side. The above surface may be positioned at a level between the third surface 200S1 and the fourth surface 200S2 of the second substrate 200.

According to embodiments, a device isolation pattern 412 may be formed inside the second substrate 200. For example, a sunken trench may be formed from the third surface 200S1 of the second substrate 200 toward the fourth surface 200S2, and an insulating material may be filled in the trench to form a device isolation pattern 412.

According to embodiments, the isolation pattern 412 may have a shape in which the width becomes narrower from the third surface 200S1 of the second substrate 200 to the fourth surface 200S2. The separation pattern 412 may include one side positioned at substantially the same level as the third surface 200S1 of the second substrate 200 and the other side facing the one side. The above surface may be positioned at a level between the third surface 200S1 and the fourth surface 200S2 of the second substrate 200.

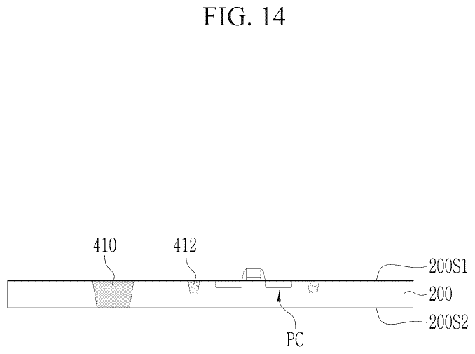

Referring to FIG. 14, a wafer thinning process may be performed on the fourth surface 200S2 of the second substrate 200 to reduce the thickness of the second substrate 200. A wafer thin film process may be performed using the first insulating pattern 410 positioned inside the second substrate 200 as a stop layer. When the first insulating pattern 410 is exposed, the wafer thinning process may be terminated.

According to embodiments, the fourth surface 200S2 of the second substrate 200 may be positioned at substantially the same level as one side of the first insulating pattern 410 by the wafer thinning process. One side of the first insulating pattern 410 may be positioned at substantially the same level as the third surface 200S1 of the second substrate 200, and the other side facing the one side may be positioned at substantially the same level as the fourth surface 200S2 of the second substrate 200. The first insulating pattern 410 may penetrate the second substrate 200 in a third direction Z perpendicular to the third surface 200S1 and the fourth surface 200S2 of the second substrate 200.

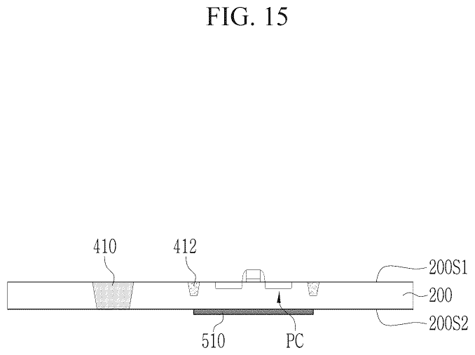

Referring to FIG. 15, a first charge shielding layer 510 may be formed on the fourth surface 200S2 of the second substrate 200.

According to embodiments, a mask pattern may be formed on the fourth surface 200S2 of the second substrate 200 excluding the area where the first charge shielding layer 510 is to be formed.

Next, a first charge shielding layer 510 may be formed on an area where a mask pattern is not formed. For example, to form the first charge shielding layer 510, a low-pressure chemical vapor deposition (LPCVD) process, a chemical vapor deposition (CVD) process, or a selective epitaxial growth (SEG) process may be performed using raw materials comprising elemental semiconductor precursors. The above elemental semiconductor precursor may include elements such as Si, Ge, etc.

According to embodiments, a dopant activation process may be performed on the first charge shielding layer 510. As the impurity activation process is performed, the impurities of the first charge shielding layer 510 may be activated. According to some embodiments, the impurity activation process may include a laser annealing process. For example, the laser annealing process may include nanosecond laser annealing, microsecond laser annealing, or millisecond laser annealing.

In the method of manufacturing a semiconductor device according to the present disclosure, by applying a laser annealing process for activating impurities, energy may be locally irradiated to a doping region to selectively heat it, thereby minimizing stress due to heat. Accordingly, de-bonding defects that may occur at the bonding surface between thin films or substrates may be effectively prevented. In addition, it is possible to realize high efficiency impurity activation while maintaining the thermal stability of the first charge shielding layer 510, thereby contributing to improved reliability and manufacturing yield of the device.

In embodiments, as the impurity activation process is performed, the first charge shielding layer 510 may include Si doped with boron (B) or SiGe doped with boron (B).

Meanwhile, in the manufacturing method of manufacturing the semiconductor device of FIGS. 8 to 11, a second charge shielding layer (e.g., the second charge shielding layer 520 of FIGS. 8 to 11) comprising Si doped with phosphorus (P), SiGe doped with phosphorus (P), Si doped with arsenic (As), or SiGe doped with arsenic (As) may be formed as an impurity activation process is performed.

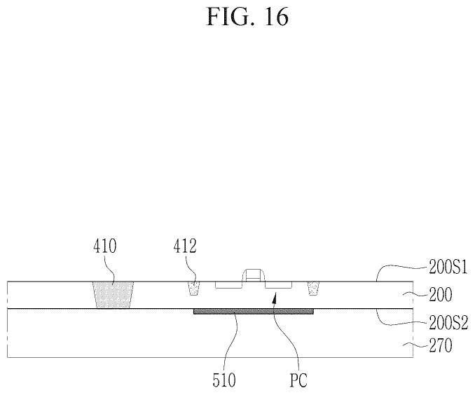

Referring to FIG. 16, a first peripheral buffer layer 270 covering the second substrate 200 and the first charge shielding layer 510 may be formed. For example, a first peripheral buffer layer 270 may be formed to cover the fourth surface 200S2 of the second substrate 200 and the first charge shielding layer 510.

According to embodiments, the first peripheral buffer layer 270 may be formed by an atomic layer deposition (ALD), chemical vapor deposition (CVD), or physical vapor deposition (PVD) process.

According to embodiments, the first peripheral buffer layer 270 may include an insulating material. According to embodiments, the first peripheral buffer layer 270 may have unique charge characteristics depending on the formation process and thermal conditions.

According to embodiments, the first peripheral buffer layer 270 may include a material having a positive charge. For example, the first peripheral buffer layer 270 may include Tetraethyl Orthosilicate (TEOS). However, it is not limited thereto, and the first peripheral buffer layer 270 may include various materials having a positive charge.

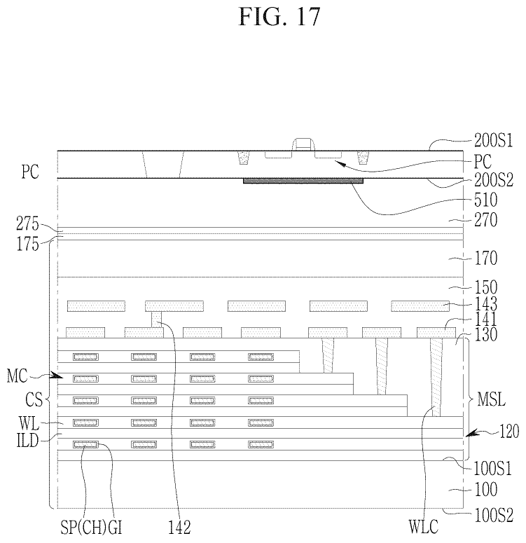

Referring to FIG. 17, a first peripheral buffer layer 270 may be adhered on the cell structure CS.

According to embodiments, a first bonding layer 175 may be formed on the cell buffer layer 170. In FIG. 17, the first bonding layer 175 is illustrated as covering the entire cell buffer layer 170, but unlike what is illustrated, the position and/or shape of the first bonding layer 175 may be variously changed.

According to embodiments, a second bonding layer 275 may be formed under the first peripheral buffer layer 270. In FIG. 17, the second bonding layer 275 is illustrated as covering the entire first peripheral buffer layer 270, but unlike what is illustrated, the position and/or shape of the second bonding layer 275 may be variously changed.

According to embodiments, a bonding process may be performed to adhere a first peripheral buffer layer 270 over a cell structure CS. For example, the first bonding layer 175 and the second bonding layer 275 may be aligned in the third direction Z. Next, the first bonding layer 175 and the second bonding layer 275 may be bonded by applying pressure and/or heat.

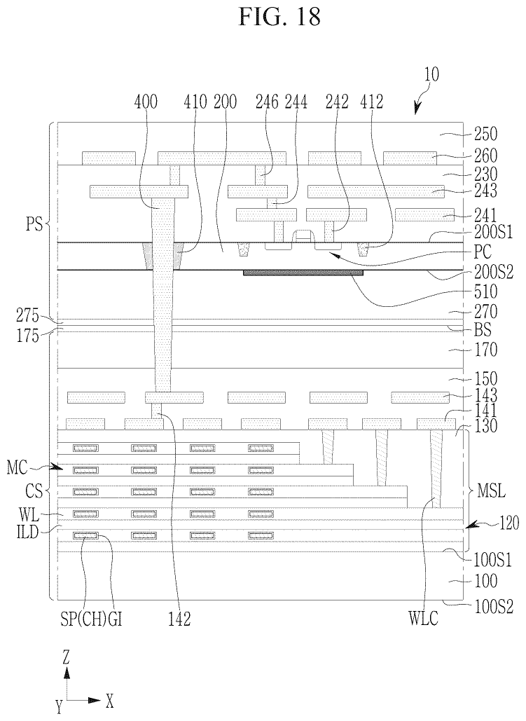

Referring to FIG. 18, a first peripheral wiring layer 241 may be formed on a peripheral circuit PC.

According to embodiments, an insulating material layer may be formed to cover a second substrate 200, a first insulating pattern 410, and a peripheral circuit PC, and a first peripheral via 242 may be formed to penetrate the insulating material layer in a third direction Z perpendicular to a third surface 200S1 of the second substrate 200. The first peripheral via 242 may include a contact connecting the first peripheral wiring layer 241 and a circuit element constituting the peripheral circuit PC. A metal layer covering an insulating material layer and a contact may be formed, and the metal layer may be patterned to form a first peripheral wiring layer 241. Through the above-described process, first and second peripheral wiring layers 241 and 243, first to third peripheral vias 242, 244 and 246 connecting a plurality of wiring layers in a third direction Z, and a first peripheral insulating layer 230 surrounding the first and second peripheral wiring layers 241 and 243 and the first to third peripheral vias 242, 244 and 246 may be formed.

In embodiments, a through via 400 may be formed while the first to third peripheral vias 242, 244 and 246 are formed. For example, the process of forming a through via 400 and the process of forming a second peripheral via 244 may be performed sequentially, and the order may be changed in various ways. However, this is not limited to the above, and the through via 400 and the second peripheral via 244 may be formed together.

According to embodiments, a first trench may be formed for forming a through via 400. For example, a seed metal layer covering the inner wall and bottom surface of the first trench may be deposited, and a plating process may be performed to fill the interior of the first trench with a metal material to form a through via 400. However, the method of forming the through-via 400 is not limited to this, and the through-via 400 may be formed in various ways.

In FIG. 18, the through via 400 is illustrated as being connected to the second peripheral wiring layer 243 and the second cell wiring layer 143 among the plurality of wiring layers, but is not limited thereto. The through via 400 is sufficient to be connected to any one of the plurality of wiring layers included in the peripheral circuit structure PS and any one of the plurality of wiring layers included in the cell structure CS.

Next, a second peripheral insulating layer 250 covering the first peripheral insulating layer 230 and a third peripheral wiring layer 260 positioned within the second peripheral insulating layer 250 may be formed.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor device comprising:
a peripheral circuit structure comprising a substrate having a first surface and a second surface facing one another, the substrate comprising first impurity regions and a second impurity region positioned between the first impurity regions; a peripheral circuit positioned on the first surface of the substrate; and a first peripheral buffer layer positioned on the second surface of the substrate;
a cell structure overlapping with the peripheral circuit structure; and
a charge shielding layer positioned between the substrate and the first peripheral buffer layer,
wherein the cell structure comprises:
a plurality of memory cells, the plurality of memory cells respectively comprising a memory transistor and a capacitor; and
a word line and a bit line connected to the memory transistor.

2. The semiconductor device of claim 1, wherein the charge shielding layer is positioned between the second surface of the substrate and the cell structure.

3. The semiconductor device of claim 1, wherein the charge shielding layer overlaps the second impurity region.

4. The semiconductor device of claim 1, wherein the charge shielding layer is entirely positioned on the second surface of the substrate.

5. The semiconductor device of claim 1, wherein the charge shielding layer comprises single crystalline silicon, polycrystalline silicon, or amorphous silicon.

6. The semiconductor device of claim 1, wherein the first impurity is of n-type, the second impurity is of p-type, the first peripheral buffer layer has a positive charge, and the charge shielding layer comprises a p-type impurity.

7. The semiconductor device of claim 6, wherein the charge shielding layer comprises B-doped Si or B-doped SiGe.

8. The semiconductor device of claim 7, further comprising a third impurity region positioned beneath the first impurity region and the second impurity region,
wherein the third impurity is of n-type, and the charge shielding layer covers the third impurity region.

9. The semiconductor device of claim 1, further comprising a second peripheral buffer layer positioned between the first peripheral buffer layer and the second surface of the substrate,
wherein the first impurity is of p-type, the second impurity is of n-type, the second peripheral buffer layer has a negative charge, and the charge shielding layer comprises a p-type impurity.

10. The semiconductor device of claim 9, wherein the charge shielding layer comprises P-doped Si, P-doped SiGe, As-doped Si, or As-doped SiGe.

11. The semiconductor device of claim 10, further comprising a third impurity region positioned beneath the first impurity region and second impurity region,
wherein the third impurity is of p-type, and the charge shielding layer covers the third impurity region.

12. A semiconductor device comprising:
a first substrate and a cell structure positioned on the first substrate, the cell structure comprising a plurality of memory cells;
a peripheral circuit structure comprising a second substrate having a first impurity regions and a second impurity region positioned between the first impurity regions; a peripheral circuit positioned on the second substrate; and a first peripheral buffer layer positioned beneath the second substrate, the peripheral circuit structure being overlapping with the cell structure; and
a charge shielding layer positioned between the first and second substrates,
wherein the cell structure comprises:
a gate stack structure in which a plurality of word lines and a plurality of interlayer insulating layers are alternately stacked,
a plurality of channel patterns arranged at intervals along a direction perpendicular to the first substrate,
bit lines extending in the direction perpendicular to the first substrate and connected to one end of each of the channel patterns, and
capacitors connected to the other ends of the respective channel patterns.

13. The semiconductor device of claim 12, wherein the second substrate comprises a first surface on which the peripheral circuit is positioned and a second surface opposite to the first surface, and the charge shielding layer is positioned between the second surface of the second substrate and the cell structure.

14. The semiconductor device of claim 12, wherein the charge shielding layer overlaps the second impurity region.

15. The semiconductor device of claim 12, wherein the charge shielding layer is entirely positioned on the second substrate.

16. The semiconductor device of claim 12, wherein the first impurity is of n-type, the second impurity is of p-type, the first peripheral buffer layer has a positive charge, and the charge shielding layer comprises a p-type impurity.

17. The semiconductor device of claim 16, wherein the charge shielding layer comprises B-doped Si or B-doped SiGe.

18. The semiconductor device of claim 12, further comprising a second peripheral buffer layer positioned between the first peripheral buffer layer and the substrate, wherein the first impurity is of p-type, the second impurity is of n-type, the second peripheral buffer layer has a negative charge, and the charge shielding layer comprises an n-type impurity.

19. The semiconductor device of claim 18, wherein the charge shielding layer comprises P-doped Si, P-doped SiGe, As-doped Si, or As-doped SiGe.

20. A semiconductor device comprising:
a first substrate and a cell structure comprising a plurality of memory cells positioned on the first substrate;
a peripheral circuit structure positioned on the cell structure, the peripheral circuit structure comprising: a second substrate comprising first impurity regions and a second impurity region positioned between the first impurity regions; a peripheral circuit positioned on the second substrate and a peripheral buffer layer positioned beneath the second substrate; and
a charge shielding layer covering a bottom surface of the second impurity region in the second substrate.
